(19) United States
(12) Patent Application Publication
(10) Pub. No.: US 2018/0203357 A1
(43) Pub. Date: Jul. 19, 2018

(54) METHOD FOR CONTROLLING RADIATION EMITTING FROM ONE OR MORE TUBULAR LAMPS IN AN EXPOSURE APPARATUS

(71) Applicant: GLUNZ & JENSEN A/S, Ringsted (DK)

(72) Inventor: Joachim SPIES, Ringsted (DK)

(21) Appl. No.: 15/742,738

(22) PCT Filed: Jul. 7, 2016
(86) PCT No.: PCT/DK2016/050239

§ 371 Date: Jan. 8, 2018

(30) Foreign Application Priority Data
Jul. 8, 2015 (DK) PA 2015 70453

(51) Int. Cl. G03F 7/20; B41C 1/00; H05B 41/38

(52) U.S. Cl. CPC G03F 7/2004; H05B 41/38; G03F 7/201; B41C 1/00

(57) ABSTRACT

There is provided method for controlling radiation emitting from one or more tubular lamps in an exposure apparatus for exposing a photosensitive element to the radiation. The method involves adjusting an adjustable ballast connected to the one or more lamps thereby adjusting the power received by the one or more lamps, wherein adjusting the ballast of the one or more lamps is based on the actual temperature and radiation of the one or more lamps.

### FIELD OF THE INVENTION

This invention pertains to a method for controlling radiation emitting from one or more tubular lamps in an exposure apparatus for exposing a photosensitive element to the radiation. Specifically, the method involves adjusting an adjustable ballast connected to the one or more lamps thereby adjusting the power received by the one or more lamps, wherein adjusting the ballast of the one or more lamps is based on the actual temperature and radiation of the one or more lamps.

### BACKGROUND OF THE INVENTION

Flexographic printing plates are well known for use in relief printing on a variety of substrates such as paper, corrugated board, films, foils and laminates. Flexographic printing plates can be prepared from photosensitive elements containing a layer of a photosensitive composition such as those described in U.S. Pat. Nos. 4,323,637 and 4,427,759. Photosensitive compositions (or photopolymerizable compositions) generally contain an elastomeric binder, at least one monomer, and a photoinitiator.

Photosensitive elements generally have the layer of the photopolymerizable composition interposed between a support and a cover sheet or multilayer cover element. Upon imagewise exposure of the photosensitive element to actinic radiation, photopolymerization of the photosensitive composition occurs in the exposed areas, thereby curing and rendering insoluble the exposed areas of the layer. The exposed element can be treated with a suitable solution or treated thermally to remove areas of the photopolymerizable layer that were not exposed which provides a printing relief suitable for use in flexographic printing.

The uniformity of the radiation emitting from each of the lamps is not constant over time, particularly over the lifetime of the lamps. During exposure, the radiation impinging the photosensitive element should be evenly distributed over the area of the exposure bed, so that the entire exposed surface of the photosensitive element is uniformly irradiated.

The plurality of light tubes when energized typically generates heat, which particularly in an enclosed environment interior to the exposure apparatus can influence the temperature of the lamps. So much heat may be generated by the lamps that the lamps overheat, and it can become difficult to maintain the lamps at a constant temperature or within a desired temperature range, causing fluctuations in emission level.

The emission level of UV lamps varies, depending on the particular lamp type used (even across different production batches from the same type of lamp), on the operation current and its frequency supplied by the lamp control unit.

The lamps age with use, where the irradiance emitted by a lamp or its intensity diminishes as the lamp is used. An integrator can be used to compensate for lamp aging to a certain degree, but either the exposures become too long or is insufficient to provide desired degree of photochemical reaction in the photosensitive element.

With ever increasing demands on quality, the current state-of-the-art flexographic printing forms may not perform as desired and have trouble meeting the ever increasing demands on quality. Exposure times vary from a few seconds to a several minutes depending upon the output of the actinic radiation source (hereafter referred to as the “lamp(s)”, distance from the lamps, desired relief depth, and the thickness of the photosensitive element. Since the photosensitive element is exposed to actinic radiation at three different steps in its conversion to a relief printing form, which includes a back exposure through the support, and image-wise exposure through the mask, and a post-exposure and finishing exposure, it is particularly desirable to create and maintain uniform conditions in the exposure apparatus so that the photosensitive element experiences consistent environment and uniform distribution of actinic radiation during each of these exposures.

US2014/0313493 discloses an exposure apparatus comprising a central control unit for controlling the output of the tubular lamps by adjusting ballast. The central control unit regulates the light intensity based on the temperature of the lamps and based on controlling the ballast. This regulation therefore uses signals from sensors that either measure the lamp temperature or the intensity of the radiation of the lamps. The regulation performed in US2014/0313493 does not take into account that the intensity of the lamps varies over time and depends on several other parameters. There is a need for an improved regulation which takes these matters into account.

### SUMMARY OF THE INVENTION

The present invention provides a method for controlling the lamp emission level in accordance with a defined set of operating conditions regarding the operating temperature, the lamp current and the lamp frequency.

Specifically there is provided a method for controlling radiation emitting from one or more tubular lamps in an exposure apparatus for exposing a photosensitive element to the radiation, said apparatus comprising an adjustable ballast connected to the one or more lamps for adjusting the power W received by the one or more lamps, wherein adjusting the ballast of the one or more lamps is based on a pre-characterization of the one or more lamps, wherein the output of the one or more lamps has been determined by the Central Control Unit, as a function of lamp current (A) and/or temperature T, optionally over the life time t, of the one or more lamps, whereby the lamp control unit is configured to adjust the ballast of the one or more lamps based on the basis of said pre-characterization to achieve a lamp output in the range of 15 to 25 mWatt/cm2, preferably 18 to 22 mWatt/cm2.

Preferably the output of the one or more lamps has been determined as a function of lamp current (A) and temperature T. Most preferably the output of the one or more lamps has been determined over the life time t of the one or more lamps.

In a preferred embodiment the temperature of the one or more lamps is measured in a distance from the one or more lamps of 0-30 cm, such as directly on the lamp surface.

The method may further comprise the step of placing the photosensitive element on an exposure bed or in proximity to the one or more lamps in a distance of 1-5 cm, and exposing the photosensitive element to the radiation irradiating from the one or more lamps after adjusting the power to the ballast in accordance with the scheme of claim 1.

The one or more lamps may comprise a plurality of tubular lamps that are adjacent and parallel to each other, and further comprising measuring irradiance emitting from the one or more lamps in proximity (i.e. 1-5 cm) to the one or more lamps.

### BRIEF DESCRIPTION OF THE DRAWINGS

FIG. 1 shows two lamp configurations of the present invention.

FIG. 2 shows graphs of lamp current adjustments over the duty cycle.

FIG. 3 shows UV-A output over lamp temperature, at different lamp current levels.

FIG. 4 shows a block diagram over the exposure system.

### DETAILED DESCRIPTION OF THE INVENTION

The invention will now be explained in more detail with reference to an embodiment in which the exposure device comprises one or more of the following functional elements:
A carrier plate for the photosensitive substrate which is temperature-controlled in order to control the substrate temperature during exposure.
A cooling system used to control the carrier plate temperature (cooled bed).
A transparent carrier plate for the photosensitive substrate in order to allow double-sided exposure.
A set of adjacent light bulbs, mounted on top and/or below the photosensitive substrate.
Minimum one temperature sensors to monitor and to control the lamp temperature.
A cooling system used to control the lamp temperature.
Minimum one UV-light sensor in order to monitor and to control the UV energy applied to the substrate.
Minimum one ballast used to provide an adjustable lamp current to the lamp(s). As an alternative, a ballast with a fixed lamp current output can used. The fixed lamp current level is based on the below mentioned dataset.
A central control unit that provides the input to the one or more adjustable ballasts, in order for them to provide the optimum lamp current according to the below mentioned dataset.
A generic dataset established for each lamp type and/or batch, defining the UV emission level as a function of time, lamp current, and temperature.

This dataset is then used to set the optimum lamp current provided by the adjustable ballast, depending on actual output status of the lamp, which is derived from the generic dataset

Examples for such generic dataset are as follows:

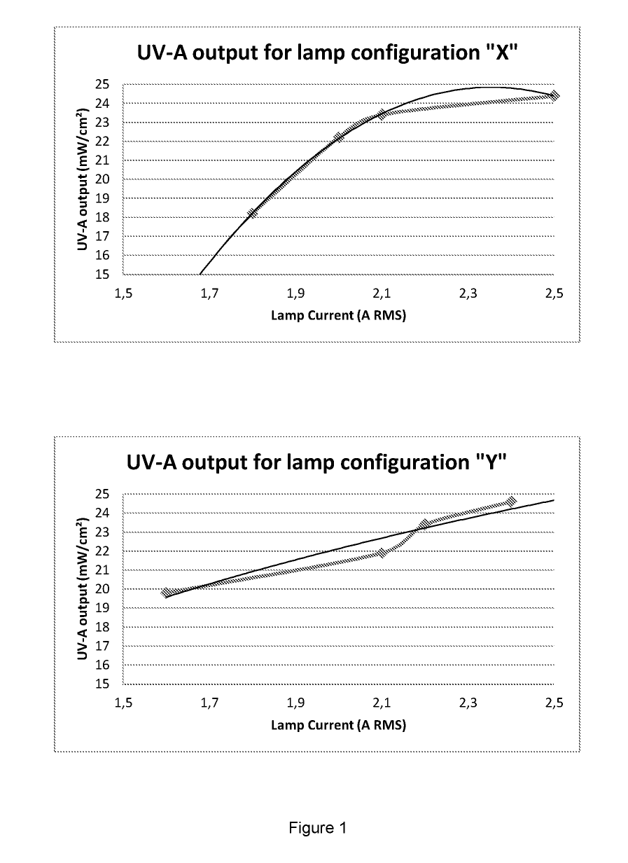

Referring to FIG. 1 there is shown the relation between the lamp current provided by the ballast, and the resulting UV-A output. The two lamp configurations shown (specific ballast+specific lamp type, X+Y) exhibit different characteristics. This generic information may be used to adjust the lamp current to an optimum level, depending on the UV-A output requirement. In the configuration “X”, the lamp current for maximum output would be set to appr. 2.1 A. If the extended lifetime is desired the optimum lamp current could be set to appr. 1.8 A.

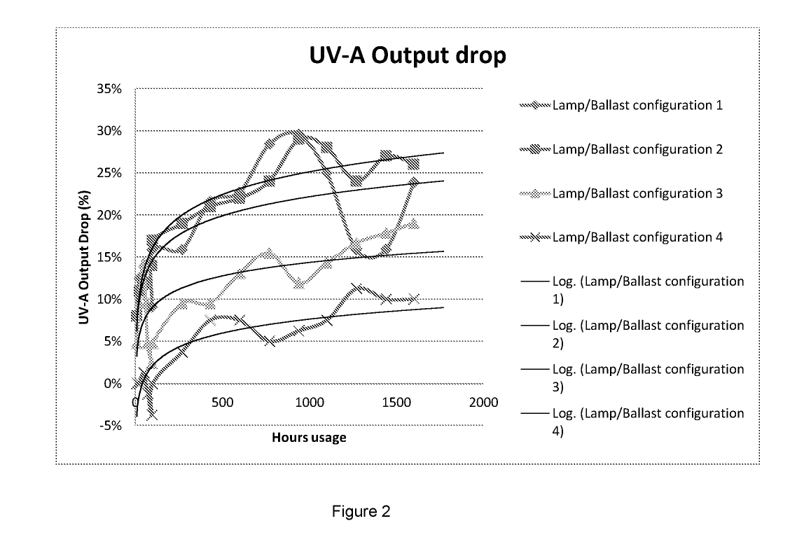

Referring to FIG. 2 there is shown a drop (in % from starting level) in UV-A output over time, at 100% duty cycle. All 4 configurations indicate individual characteristics, which can be shown as logarithmic functions. Based on these functions, the lamp current can be adjusted over duty cycle time in order to compensate for the shown drop.

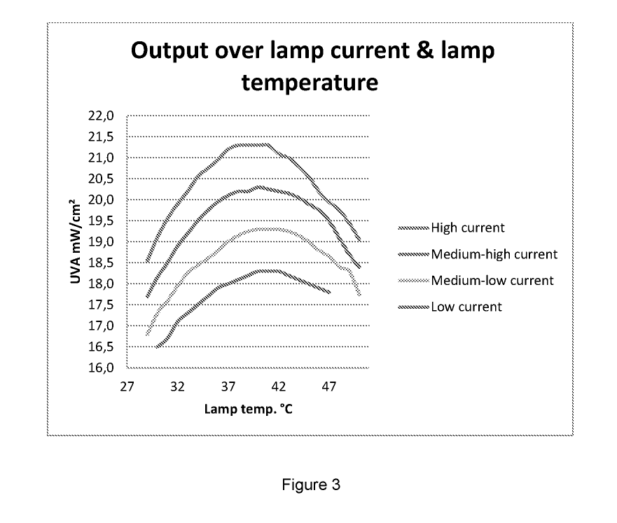

Referring to FIG. 3 there is shown UV-A output over lamp temperature, at different lamp current levels. This temperature characteristic is varying slightly from lamp type to lamp type. Such knowledge is important in order to determine and ensure optimum temperature conditions for each individual lamp type.

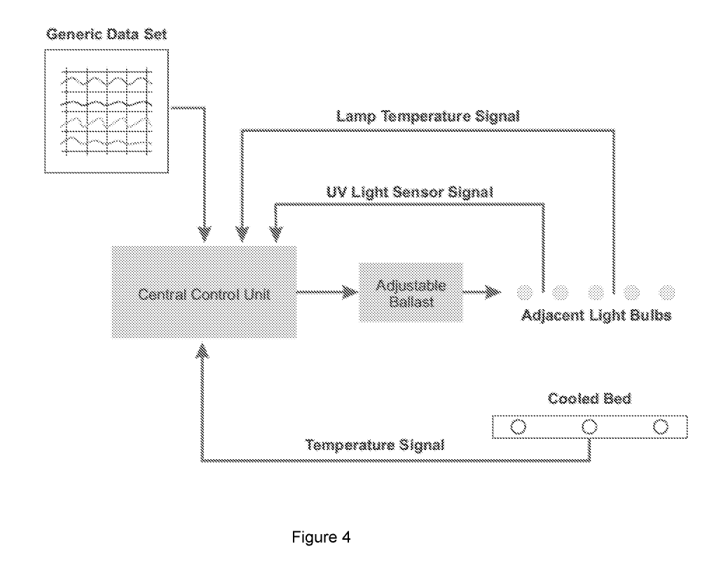

Finally, for illustrative purposes reference is made to FIG. 4, which is a block diagram over the exposure system.

1. A method for controlling radiation emitting from one or more tubular lamps in an exposure apparatus for exposing a photosensitive element to the radiation, said apparatus comprising a central control unit and an adjustable ballast connected to the one or more lamps for adjusting the power W (ballast) received by the one or more lamps, wherein the method comprises the step of adjusting the ballast of the one or more lamps is based on a pre-characterization of the one or more lamps, said pre-characterization determining the output of the one or more lamps has been determined as a function of lamp current (A) and/or temperature T, optionally over the life time t, of the one or more lamps, whereby the central control unit is configured to adjust the ballast of the one or more lamps based on the basis of said pre-characterization to achieve a lamp output in the range of 15 to 25 mWatt/cm2.

2. The method of claim 1, wherein the output of the one or more lamps has been determined as a function of lamp current (A) and temperature T.

3. The method of claim 1, wherein the output of the one or more lamps has been determined over the life time t of the one or more lamps.

4. The method of claim 1, wherein the temperature of the one or more lamps is measured in a distance from the one or more lamps of 0-30 cm.

5. The method of claim 1 further comprising placing the photosensitive element on an exposure bed, and exposing the photosensitive element to the radiation irradiating from the one or more lamps after adjusting the power to the ballast.

6. The method of claim 1, wherein the target irradiance is 18 to 22 mWatt/cm2.

7. The method of claim 1, wherein the one or more lamps comprises a plurality of tubular lamps that are adjacent and parallel to each other, and further comprising measuring irradiance emitting from the one or more lamps in proximity (i.e. 2-4 cm) to the one or more lamps.

8. The method of claim 1, wherein the exposure apparatus for exposing a photosensitive element to the radiation has a cooled bed configuration.

9. An exposure apparatus comprising:
an adjustable ballast connected to one or more tubular lamps for adjusting the power W (ballast) received by the one or more lamps,
a control unit for adjusting the ballast of the one or more lamps based on a pre-characterization of the one or more lamps, wherein the output of the one or more lamps has been determined as a function of lamp current (A) and/or temperature T, optionally over the life time t, of the one or more lamps, whereby the central control unit is configured to adjust the ballast of the one or more lamps based on the basis of said pre-characterization to achieve a lamp output in the range of 15 to 25 mWatt/cm2.

10. The exposure apparatus according to claim 9, wherein the control unit is configured to implement a method for controlling radiation emitting from one or more tubular lamps in an exposure apparatus for exposing a photosensitive element to the radiation said apparatus comprising a central control unit and an adjustable ballast connected to the one or more lamps for adjusting the power W (ballast) received by the one or more lamps, wherein the method comprises the step of adjusting the ballast of the one or more lamps is based on a pre-characterization of the one or more lamps, said pre-characterization determining the output of the one or more lamps has been determined as a function of lamp current (A) and/or temperature T, optionally over the life time t, of the one or more lamps, whereby the central control unit is configured to adjust the ballast of the one or more lamps based on the basis of said pre-characterization to achieve a lamp output in the range of 15 to 25 mWatt/cm2.
